(19) United States
(12) Patent Application Publication
(10) Pub. No.: US 2026/0013397 A1
(43) Pub. Date: Jan. 8, 2026

(54) MEMS DEVICE AND METHOD FOR FORMING THE SAME

(71) Applicant: TAIWAN SEMICONDUCTOR MANUFACTURING COMPANY LTD., HSINCHU (TW)

(72) Inventors: CHING-HUI LIN, TAICHUNG CITY (TW); PO-CHEN YEH, NEW TAIPEI CITY (TW); FU-CHUN HUANG, HSINCHU COUNTY (TW); CHAO-HUNG CHU, KEELUNG CITY (TW); YI-HSIEN CHANG, CHANGHUA COUNTY (TW); CHUN-REN CHENG, HSINCHU CITY (TW); SHIH-FEN HUANG, HSINCHU COUNTY (TW)

(21) Appl. No.: 18/672,046

(22) Filed: May 23, 2024

(51) Int. Cl. H10N 30/88; H10N 30/02

(52) U.S. Cl. CPC H10N 30/883; H10N 30/02

(57) ABSTRACT

A MEMS device includes a substrate, a first electrode layer, a second electrode layer, a piezoelectric layer, a first dielectric layer and a second dielectric layer. The substrate includes an environment port in communication with an ambient environment. The first electrode layer is disposed over the substrate, the second electrode layer is disposed over the first electrode layer, and the piezoelectric layer is disposed between the first electrode layer and the second electrode layer. The first dielectric layer and the second dielectric layer include different materials.

### BACKGROUND

Piezoelectric microelectromechanical system (MEMS) devices, fabricated using micromachining technologies, provide a versatile platform for various high-performance sensors, actuators, energy harvesters, filters and oscillators (main building blocks in radio frequency front-ends for wireless communications). Piezoelectric MEMS devices introduce their own requirements into integration processes.

### BRIEF DESCRIPTION OF THE DRAWINGS

Aspects of the present disclosure are best understood from the following detailed description when read with the accompanying figures. It should be noted that, in accordance with the standard practice in the industry, various features are not drawn to scale. In fact, the dimensions of the various features may be arbitrarily increased or reduced for clarity of discussion.

FIG. 1 is a schematic drawing of a MEMS device at a fabrication stage constructed according to aspects of the present disclosure in one or more embodiments.

FIG. 2 is a schematic drawing of the MEMS device at a fabrication stage subsequent to that shown in FIG. 1 according to aspects of the present disclosure in one or more embodiments.

FIG. 3A is a schematic drawing of the MEMS device at a fabrication stage subsequent to that shown in FIG. 2 according to aspects of the present disclosure in one or more embodiments.

FIG. 3B is a partially enlarged view of a circle A1 in FIG. 3A.

FIG. 3C is a partially enlarged view of a circle A2 in FIG. 3A.

FIG. 4 is a schematic drawing of the MEMS device at a fabrication stage subsequent to that shown in FIG. 3A according to aspects of the present disclosure in one or more embodiments.

FIG. 5 is a schematic drawing of the MEMS device at a fabrication stage subsequent to that shown in FIG. 4 according to aspects of the present disclosure in one or more embodiments.

FIG. 6 is a schematic drawing of the MEMS device at a fabrication stage subsequent to that shown in FIG. 5 according to aspects of the present disclosure in one or more embodiments.

FIG. 7 is a schematic drawing of a MEMS device at a fabrication stage constructed according to aspects of the present disclosure in one or more embodiments.

FIG. 8 is a schematic drawing of the MEMS device at a fabrication stage subsequent to that shown in FIG. 7 according to aspects of the present disclosure in one or more embodiments.

FIG. 9A is a schematic drawing of the MEMS device at a fabrication stage subsequent to that shown in FIG. 8 according to aspects of the present disclosure in one or more embodiments.

FIG. 9B schematic drawing of the MEMS device at a fabrication stage subsequent to that shown in FIG. 8 according to aspects of the present disclosure in one or more embodiments.

FIG. 10 is a schematic drawing of the MEMS device at a fabrication stage subsequent to that shown in FIG. 9A according to aspects of the present disclosure in one or more embodiments.

FIG. 11 is a schematic drawing of the MEMS device at a fabrication stage subsequent to that shown in FIG. 10 according to aspects of the present disclosure in one or more embodiments.

FIG. 12 is a flowchart representing a method for forming a MEMS device according to aspects of the present disclosure.

### DETAILED DESCRIPTION

The following disclosure provides many different embodiments, or examples, for implementing different features of the provided subject matter. Specific examples of elements and arrangements are described below to simplify the present disclosure. These are, of course, merely examples and are not intended to be limiting. For example, the formation of a first feature over or over a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of brevity and clarity and does not in itself dictate a relationship between the various embodiments and/or configurations discussed.

Further, spatially relative terms, such as “beneath,” “below,” “lower,” “above,” “upper,” “on” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

As used herein, the terms such as “first,” “second” and “third” describe various elements, components, regions, layers and/or sections, but these elements, components, regions, layers and/or sections should not be limited by these terms. These terms may be only used to distinguish one element, component, region, layer or section from another. The terms such as “first,” “second” and “third” when used herein do not imply a sequence or order unless clearly indicated by the context.

Notwithstanding that the numerical ranges and parameters setting forth the broad scope of the disclosure are approximations, the numerical values set forth in the specific examples are reported as precisely as possible. Any numerical value, however, inherently contains certain errors necessarily resulting from the standard deviation found in the respective testing measurements. Also, as used herein, the terms “substantially,” “approximately” or “about” generally mean within a value or range that can be contemplated by people having ordinary skill in the art. Alternatively, the terms “substantially,” “approximately” or “about” mean within an acceptable standard error of the mean when considered by one of ordinary skill in the art. People having ordinary skill in the art can understand that the acceptable standard error may vary according to different technologies. Other than in the operating/working examples, or unless otherwise expressly specified, all of the numerical ranges, amounts, values and percentages such as those for quantities of materials, durations of times, temperatures, operating conditions, ratios of amounts, and the likes thereof disclosed herein should be understood as modified in all instances by the terms “substantially,” “approximately” or “about.” Accordingly, unless indicated to the contrary, the numerical parameters set forth in the present disclosure and attached claims are approximations that can vary as desired. At the very least, each numerical parameter should be construed in light of the number of reported significant digits and by applying ordinary rounding techniques. Ranges can be expressed herein as being from one endpoint to another endpoint or between two endpoints. All ranges disclosed herein are inclusive of the endpoints, unless specified otherwise.

A thick dielectric layer is usually needed to provide protection to a piezoelectric MEMS device. In such approaches, a planarization such as a chemical mechanical polish (CMP) operation that is commonly used in semiconductor manufacturing operations is performed to provide a smooth and even surface. However, due to mechanical sensitivity of piezoelectric material, CMP may cause unpredictable damage to a piezoelectric film adopted in a piezoelectric MEMS device. Further, a thick dielectric layer may increase overall film stiffness and adversely affect device performance.

The present disclosure therefore provides a MEMS device and a method that introduces a bi-layer structure that is able to provide sufficient protection to the piezoelectric MEMS device with less thickness. Further, no planarization operation is required in this bi-layer structure. Therefore, mechanical influence on the piezoelectric MEMS device is mitigated.

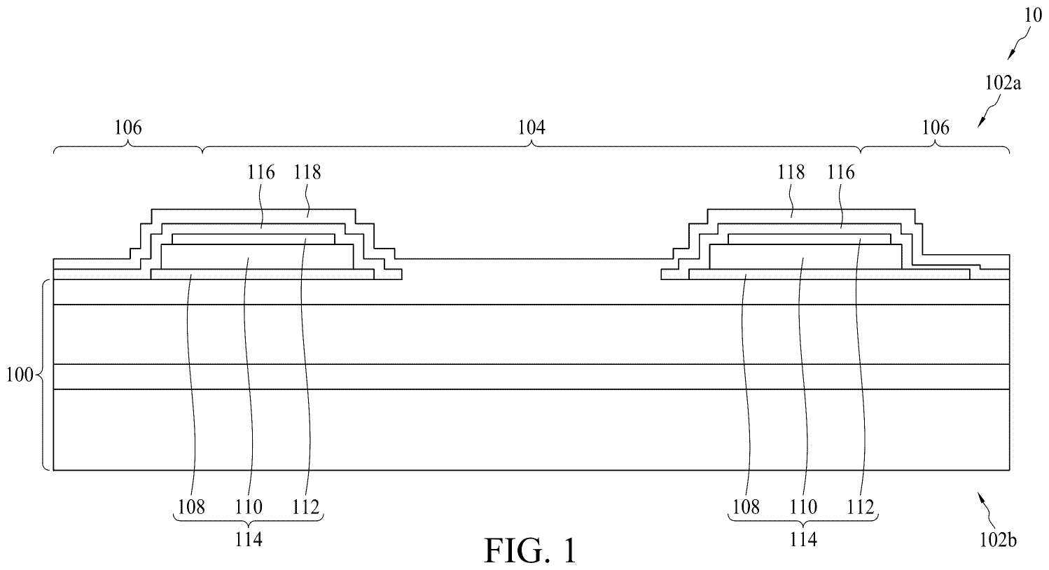

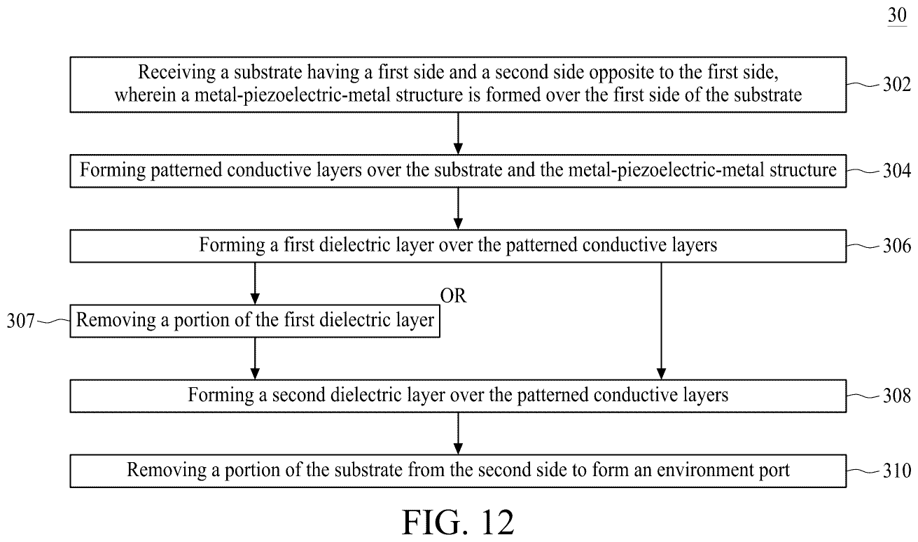

FIGS. 1 to 6 are partial cross-sectional views of various stages in a formation of a MEMS device in accordance with aspects of the present disclosure in one or more embodiments. The corresponding operations are reflected schematically in a flowchart shown in FIG. 12.

As shown in FIG. 1, a substrate 100 is received. The substrate 100 may be a semiconductor substrate, and the semiconductor substrate may be, for example but not limited thereto, a bulk substrate of monocrystalline silicon or a bulk substrate of some other semiconductor. In some embodiments, a plurality of integrated circuit (IC) devices (not shown) may be formed over or in the substrate 100. The plurality of devices may include, for example but not limited thereto, insulated-gate field-effect transistors (IGFETs), metal-oxide-semiconductor field-effect transistors (MOSFETs), some other transistors, or a combination of the foregoing. In some embodiments, a back-end-of-line (BEOL) interconnect structure (not shown) may be formed over the substrate 100 on a front side 102a of the substrate 100. The BEOL interconnect structure is configured to electrically connect the IC devices to one another and/or to other devices, such as a subsequently-formed MEMS device. In some embodiments, the BEOL interconnect structure includes a plurality of dielectric layers, and a plurality of wiring layers and a plurality of vias disposed in the plurality of dielectric layers. The wiring layers are electrically connected by the vias such that electric paths are constructed. The dielectric layers include, for example but not limited thereto, silicon dioxide, a low-k dielectric, some other dielectric, or a combination thereof. As used herein, a low-k dielectric is a material having a dielectric constant less than approximately 3.9. The wiring layers and the vias include conductive material such as, for example but not limited thereto, aluminum, copper, aluminum copper, tungsten, some other conductive materials, or a combination thereof.

In some embodiments, the substrate 100 has a MEMS region defined to accommodate a MEMS device and a circuit region defined to accommodate the abovementioned IC devices. In some embodiments, the MEMS region for accommodating the MEMS device can be further defined to have a movable portion 104 and an anchor portion 106, wherein the anchor portion 106 surrounds the movable portion 104.

Still referring to FIG. 1, an electrode layer 108 is formed over the substrate 100 on the front side 102a. Further, the electrode layer 108 is formed in the MEMS region. The electrode layer 108 may include copper, aluminum, aluminum copper, molybdenum, gold, platinum, some other conductive materials, or a combination thereof. In some embodiments, the electrode layer 108 may be formed by depositing a conductive material over the substrate 100 on the front side 102a, and patterning such conductive material, but the disclosure is not limited thereto.

In some embodiments, after the forming of the electrode layer 108, a piezoelectric layer 110 is formed over the electrode layer 108 in the MEMS region. The piezoelectric layer 110 includes piezoelectric materials such as, for example but not limited thereto, aluminum nitride, zinc oxide, lead zirconate titanate (Pb(Zr,Ti)O₃, PZT), some other piezoelectric material, or a combination thereof. In some embodiments, the piezoelectric layer 110 may be formed by depositing the piezoelectric material over the substrate 100 and the electrode layer 108, and patterning such piezoelectric material, but the disclosure is not limited thereto.

In some embodiments, after the forming of the piezoelectric layer 110, another electrode layer 112 is formed. The electrode layer 112 may include copper, aluminum, aluminum copper, molybdenum, gold, platinum, some other conductive materials, or a combination thereof. In some embodiments, the electrode layer 112 may include a material same as that of the electrode layer 108. In some embodiments, the electrode layer 112 may be formed by depositing a conductive material over the substrate 100, the electrode layer 108 and the piezoelectric layer 110, and patterning such conductive material, but the disclosure is not limited thereto.

As shown in FIG. 1, the piezoelectric layer 110 is disposed between the electrode layer 108 and the electrode layer 112 to form a metal-piezoelectric-metal structure 114. In some embodiments, the electrode layer 108 may be referred to as a bottom electrode, and the electrode layer 112 may be referred to as a top electrode. The piezoelectric layer 110 is configured to sense motion and to convert the motion into an electrical signal through the bottom electrode (i.e., the electrode layer 108) and the top electrode (i.e., the electrode layer 112). Thus, the metal-piezoelectric-metal structure 114 serves as a MEMS device that may be used in a microphone, an accelerometer, a motion sensor, a pressure sensor, or a gyroscope. In addition, the piezoelectric layer 110 is configured to actuate input electrical signal from IC device. The metal-piezoelectric-metal structure 114 serves as a MEMS device that may be used in a micro-speaker, a micropump, or an autofocus device. Additionally, the metal-piezoelectric-metal structure 114 is electrically coupled to an IC device in an IC region through the BEOL interconnect structure, though not shown.

Still referring to FIG. 1, in some embodiments, a diffusion barrier layer 116 and a dielectric layer 118 may be formed over the metal-piezoelectric-metal structure 114 and the substrate 100 after the forming of the electrode layer 112. In some embodiments, the diffusion barrier layer 116 and the dielectric layer 118 may be formed to cover the metal-piezoelectric-metal structure 114 and extend from the anchor portion 106 to the movable portion 104. However, in some embodiments, the diffusion barrier layer 116 may be formed to cover the metal-piezoelectric-metal structure 114 and a portion of the substrate 100 in the anchor portion 106. In such embodiments, portions of the movable portion 104 in the MEMS region are free of the diffusion barrier layer 116 in order to reduce film stiffness.

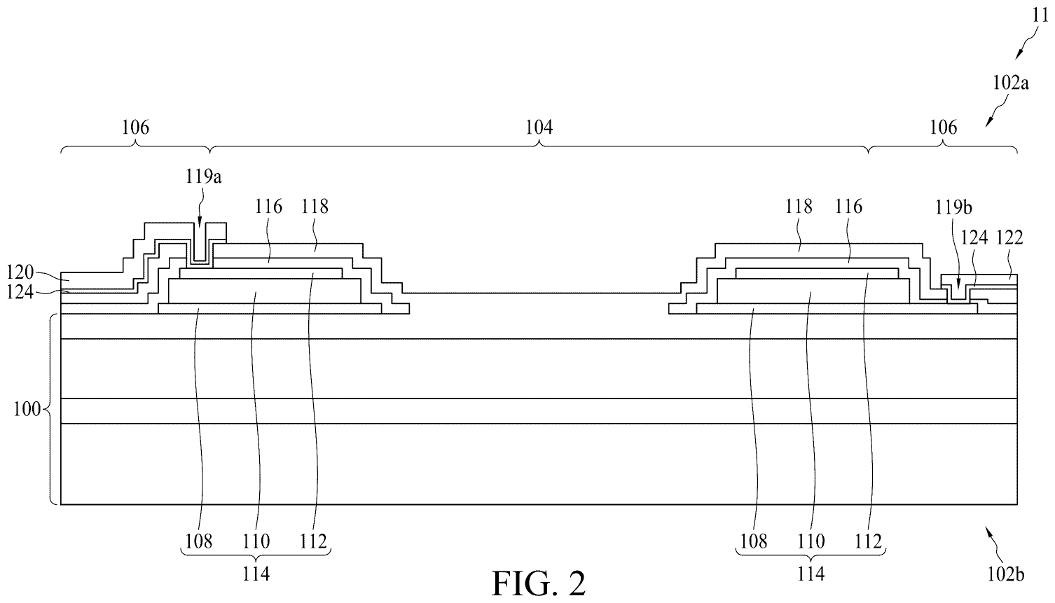

Referring to FIG. 2, in some embodiments, patterned conductive layers 120 and 122 are formed over the substrate 100 and the metal-piezoelectric-metal structure 114. Further, the patterned conductive layers 120 and 122 are formed in the anchor portion 106. In some embodiments, openings 119a and 119b are formed over the metal-piezoelectric-metal structure 114. The opening 119a penetrates the dielectric layer 118 and the diffusion barrier layer 116 to expose a portion of the electrode layer 112, and the opening 119b penetrates the dielectric layer 118 and the diffusion barrier layer 116 to expose a portion of the electrode layer 108. A conductive material is subsequently formed in the openings 119a and 119b, and over the metal-piezoelectric-metal structure 114 and the substrate 100. In some embodiments, the conductive material includes one or more conductive materials, such as tungsten, aluminum, copper, aluminum copper, gold, silver, or platinum, but the disclosure is not limited thereto. In some embodiments, the conductive material is formed by physical vapor deposition (PVD), but the disclosure is not limited thereto. In some embodiments, a thickness of the conductive material is between approximately 3,000 angstroms (Å) and approximately 10,000 Å, but the disclosure is not limited thereto. In some embodiments, a glue and/or diffusion barrier layer 124 may be formed prior to the forming of the conductive material in order to improve adhesion between the conductive material and the underlying layers and to mitigate diffusion into the dielectric layer 118. The conductive material is then patterned to form the patterned conductive layers 120 and 122. The patterned conductive layers 120 and 122 are separated from each other. As shown in FIG. 2, the patterned conductive layer 120 is formed over a portion of the metal-piezoelectric-metal structure 114 and coupled to the electrode layer 112 through the opening 119a, while the patterned conductive layer 122 is formed over another portion of the metal-piezoelectric-metal structure 114 and coupled to the electrode layer 108 through the opening 119b.

As shown in FIG. 2, a step height is formed between a top surface of the patterned conductive layer 120 and the dielectric layer 118, and a step height is formed between a top surface of the patterned conductive layer 122 and the dielectric layer 118. As mentioned above, the thickness of the patterned conductive layers 120 and 122 is between approximately 3,000 Å and approximately 10,000 Å, while a thickness of the diffusion barrier layer 124 and/or the glue layer 124 may be between approximately 100 Å and 1,000 Å. Therefore, the step heights may be greater than 3,000 Å or greater than 10,000 Å.

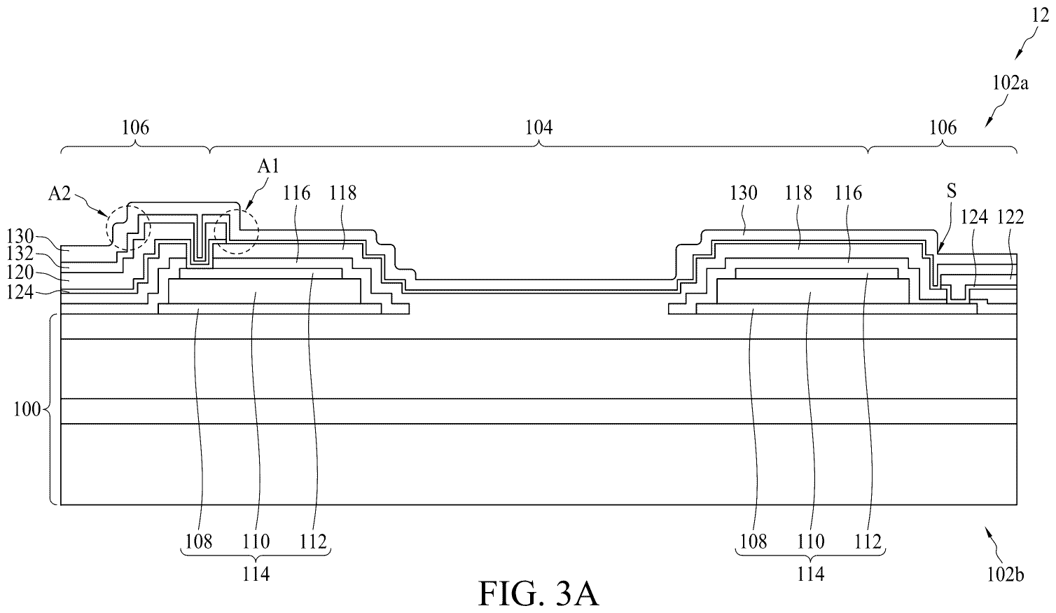

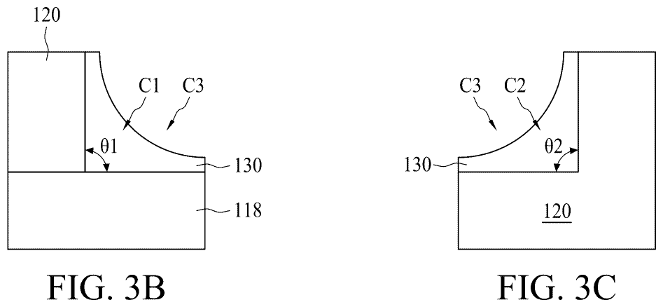

Please refer to FIGS. 3A to 3C, wherein FIG. 3B is a partially enlarged view of a circle A1 in FIG. 3A, and FIG. 3C is a partially enlarged view of a circle A2 in FIG. 3A. In some embodiments, a dielectric layer 130 is formed over the substrate 100 and the metal-piezoelectric-metal structure 114. In some embodiments, a glue layer 132 and/or a diffusion barrier layer 132 may be formed prior to the forming of the dielectric layer 130. The glue layer 132 and/or the diffusion barrier layer 132 is formed in order to improve adhesion between the dielectric layer 130 and the underlying layers and to mitigate diffusion into the dielectric layer 130. In some embodiments, the dielectric layer 130 may include silicon oxide, but the disclosure is not limited thereto. In some embodiments, a thickness of the dielectric layer 130 is between approximately 100 Å and approximately 5,000 Å, but the disclosure is not limited thereto.

As shown in FIGS. 3A to 3C, a corner C1 (shown in FIG. 3B) may be formed by the patterned conductive layer 120 and the dielectric layer 118, wherein the corner C1 has an included angle θ1 defined by the patterned conductive layer 120 and the dielectric layer 118. In some embodiments, the included angle θ1 of the corner C1 is equal to or less than 90°. A corner C2 (shown in FIG. 3C) may be formed by the patterned conductive layer 120, wherein the corner C2 has an included angle θ2 defined by the patterned conductive layer 120. In some embodiments, the included angle θ2 of the corner C2 is equal to or less than 90°. Additionally, a seam S may be formed between the patterned conductive layer 122 and the dielectric layer 118. In some embodiments, due to the step height between the patterned conductive layer 120 and the dielectric layer 118, and the step height between the patterned conductive layer 122 and the dielectric layer 118, an uneven topography is created. Further, it is difficult to fill the corners C1 and C2 and the seam S due to such uneven topography. To mitigate such issue, the dielectric layer 130 is formed by a chemical vapor deposition (CVD) with a liquid phase precursor, such as tetraethoxysilane (TEOS). In some embodiments, the dielectric layer 130 is formed using a flowable CVD (FCVD). In such embodiments, the corners C1 and C2 and the seam S can be filled with the dielectric layer 130.

In some comparative approaches, when a dielectric layer is formed without the liquid phase precursor, it is found that a void is usually sealed within the corner C1 and such dielectric layer, sealed within the corner C2 and such dielectric layer, and/or sealed within the seam S and such dielectric layer. In contrast to those comparative approaches, in some embodiments of the present disclosure, the corners C1 and C2 and the seam S can be filled with the dielectric layer 130. Further, the dielectric layer 130 has a corner C3 corresponding to the corners C1 and C2. The corner C3 of the dielectric layer 130 has a concave surface, as shown in FIGS. 3B and 3C.

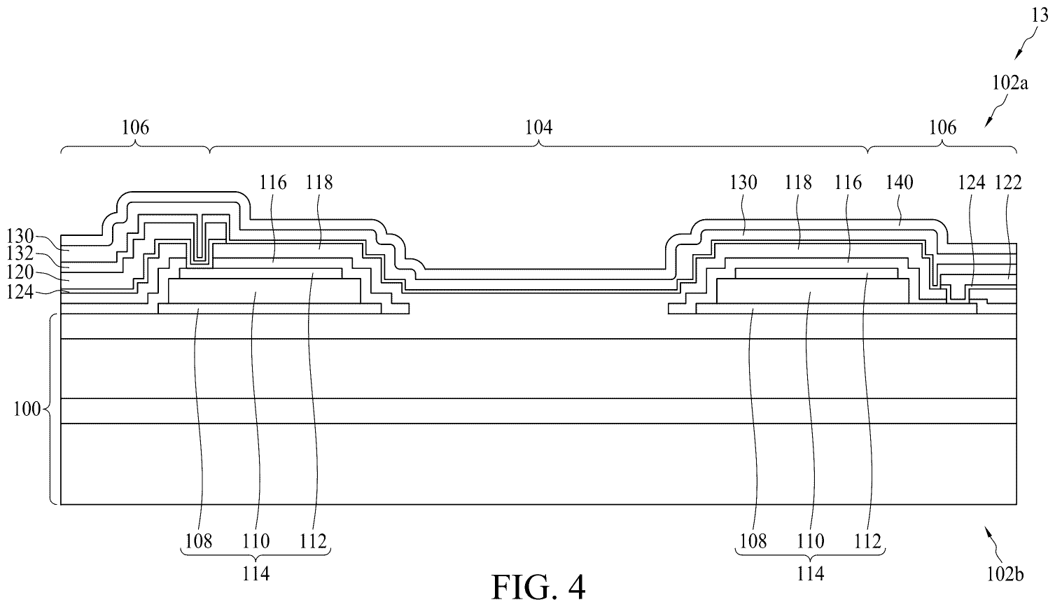

Referring to FIG. 4, in some embodiments, a dielectric layer 140 is formed over the dielectric layer 130. The dielectric layer 140 includes a material different from that of the dielectric layer 130. Further, the material of the dielectric layer 140 has a moisture resistance greater than that of a material of the dielectric layer 130. In some embodiments, the dielectric layer 140 includes silicon nitride, aluminum nitride, silicon oxynitride or aluminum oxynitride, but the disclosure is not limited thereto. In some embodiments, a thickness of the dielectric layer 140 is between approximately 1,000 Å and approximately 5,000 Å, but the disclosure is not limited thereto. In some embodiments, the dielectric layer 130 and the dielectric layer 140 form a bi-layer structure. It should be noted that due to the concave surface provided by the dielectric layer 130, the dielectric layer 140 can be formed to sufficiently cover the patterned conductive layers 120 and 122, and the metal-piezoelectric-metal structure 114. In some comparative embodiments, it is found that voids may be formed in the dielectric layer 140 if the dielectric layer 130 is absent. Such voids may develop into a crack during subsequent operations and ultimately damage the entire MEMS device.

Further, it is found that with same thicknesses, the abovementioned materials of dielectric layer 140 provide moisture protection to the metal-piezoelectric-metal structure 114 better than to a moisture protection that would be provided by silicon oxide. In some comparative approaches, to achieve such moisture protection, a thickness of a silicon oxide layer would need to be greater than 60,000 Å. Such a thickness would result in an excessive film stiffness that would adversely impact performance of the MEMS device. In still other comparative approaches, as a counterpart to such problem, portions of the thick silicon oxide layer are removed from the movable portion 104 of the MEMS region for reducing the abovementioned film stiffness, and thus process cost is increased. In contrast to those comparative approaches, in some embodiments of the present disclosure, the dielectric layer 140 is able to provide sufficient moisture protection with a less thickness, thus reducing film stiffness. Accordingly, actuation performance of the MEMS device is improved. Additionally, with such bi-layer structure, planarization is not needed. Therefore, the MEMS device is protected from external mechanical stress or force.

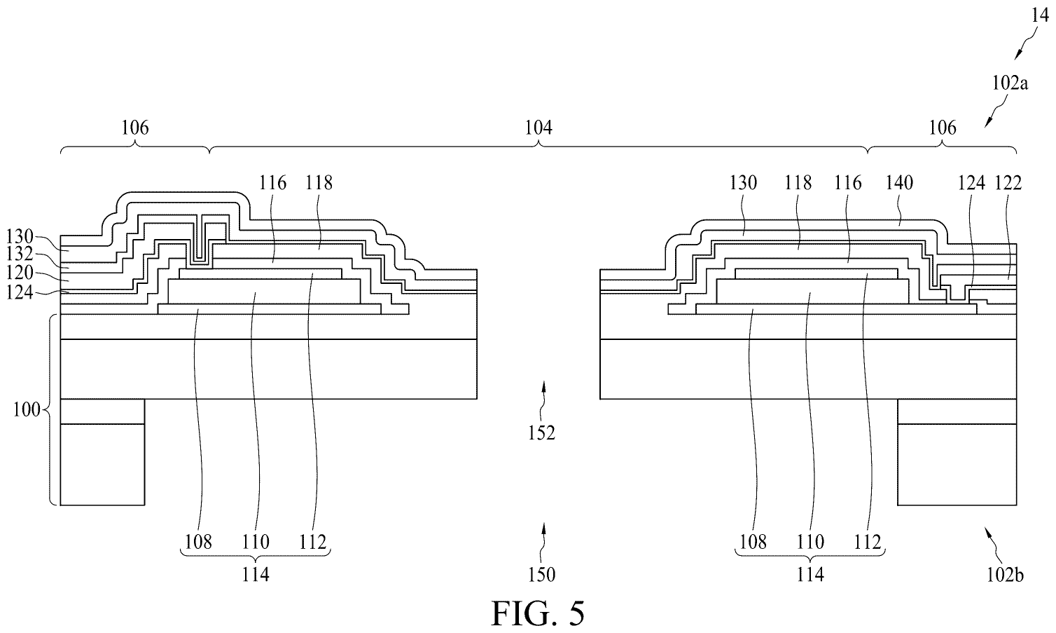

Referring to FIG. 5, in some embodiments, a portion of the substrate 100 is removed from a backside 102b to form an environment port 150 in communication with an ambient environment. In some embodiments, a portion of the substrate 100, a portion of the dielectric layer 118, a portion of the dielectric layer 130, and a portion of the dielectric layer 140 are removed from the movable portion 104 of the MEMS region to form a hole 152. As shown in FIG. 5, the hole 152 is coupled to the environment port 150. Further, a diameter or a width of the hole 152 is less than a diameter or a width of the environment port 150. In such embodiments, a portion of the substrate 100, a portion of the dielectric layer 118, a portion of the dielectric layer 130, and a portion of the dielectric layer 140 are exposed through the hole 152 and form sidewalls of the hole 152, as shown in FIG. 5.

Accordingly, a MEMS device 14 is formed as shown in FIG. 5. In some embodiments, the MEMS device 14 includes a substrate 100, a metal-piezoelectric-metal structure 114 over a front side 102a of the substrate 100, patterned conductive layers 120 and 122 over the metal-piezoelectric-metal structure 114, a dielectric layer 130 over the metal-piezoelectric-metal structure 114, and a dielectric layer 140 over the dielectric layer 130. The metal-piezoelectric-metal structure 114 includes an electrode layer 108 serving as a bottom electrode, an electrode layer 112 serving as a top electrode, and a piezoelectric layer 110 between the bottom and top electrodes 108 and 112. The patterned conductive layer 120 is coupled to the top electrode 112 and the patterned conductive layer 122 is coupled to the bottom electrode 108. The dielectric layer 130 covers the patterned conductive layers 120 and 122, the metal-piezoelectric-metal structure 114 and the substrate 100. Further, the dielectric layers 130 and 140 extend from the anchor portion 106 into the movable portion 104. As mentioned above, the dielectric layers 130 and 140 form a bi-layer structure. In the bi-layer structure, the dielectric layer 140 provides moisture protection, while the dielectric layer 130 provides an improved filling result such that the dielectric layer 140 can be thoroughly formed over the substrate 100, the metal-piezoelectric-metal structure 114, and the patterned conductive layers 120 and 122.

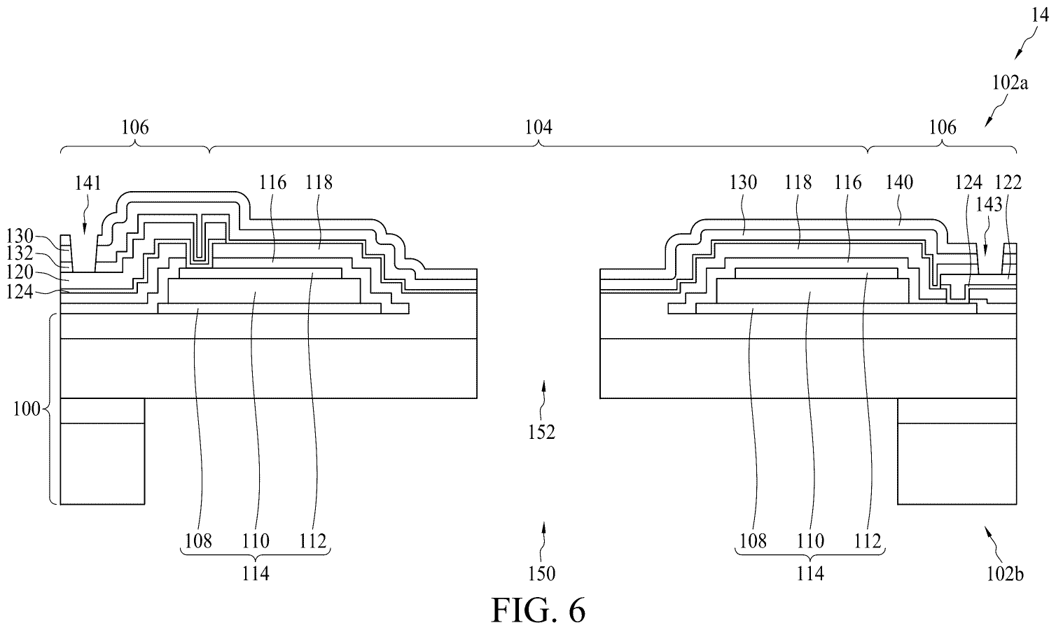

In some embodiments, as shown in FIG. 6, a portion of the dielectric layer 140, a portion of the dielectric layer 130, and a portion of the glue layer 132 and/or diffusion barrier layer 132 may be removed to form openings 141 and 143. The opening 141 may expose a portion of the patterned conductive layer 120, and the opening 143 may expose a portion of the patterned conductive layer 122. In some embodiments, the patterned conductive layers 120 and 122 serve as topmost metal layers, and a probing can be performed on the patterned conductive layers 120 and 122 through the openings 141 and 143. Additionally, the forming of the openings 141 and 143 may be performed prior to or after the forming of the environment port 150.

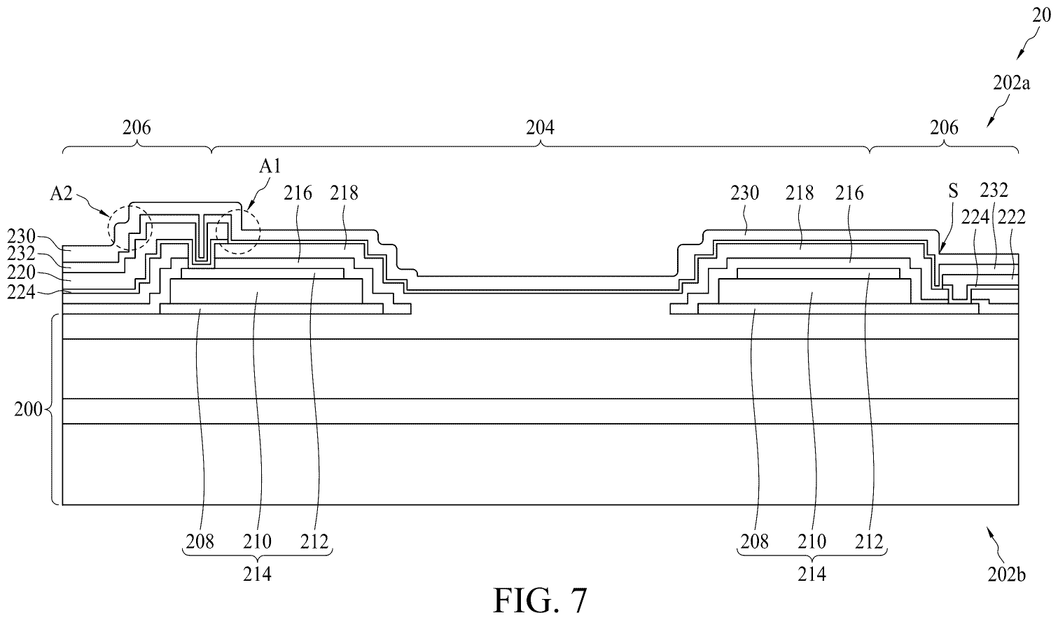

FIGS. 7 to 11 are partial cross-sectional views of various stages in a formation of a MEMS device in accordance with aspects of the present disclosure in one or more embodiments. The corresponding operations are reflected schematically in a flowchart shown in FIG. 12.

As shown in FIG. 7, a substrate 200 is received. The substrate 200 may be a semiconductor substrate, and the semiconductor substrate may include materials similar to those of the substrate 200; therefore, such details are omitted for brevity. In some embodiments, IC devices (not shown) and a BEOL interconnect structure (not shown) may be formed over or in the substrate 200 on a front side 202a of the substrate 200. The BEOL interconnect structure is configured to electrically connect the IC devices to one another and/or to other devices, such as a subsequently-formed MEMS device. Details of the BEOL interconnect structure may be similar to those described above; therefore, such details are omitted for brevity. Further, in some embodiments, the substrate 200 has a MEMS region defined to accommodate a MEMS device and a circuit region defined to accommodate the abovementioned IC devices. In some embodiments, the MEMS region for accommodating the MEMS device can be further defined to have a movable portion 204 and an anchor portion 206, wherein the anchor portion 206 surrounds the movable portion 204.

As shown in FIG. 7, an electrode layer 208, a piezoelectric layer 210 and an electrode layer 212 are formed over the substrate 200 on the front side 202a. Materials of the electrode layers 208 and 212 may be similar to those described above; therefore, such details are omitted. Materials of the piezoelectric layer 210 may be similar to those described above; therefore, such details are also omitted. In some embodiments, operations for forming the electrode layer 208, the piezoelectric layer 210 and the electrode layer 212 may be similar to the operations for forming the electrode layer 108, the piezoelectric layer 110 and the electrode layer 112; therefore, such details are omitted for brevity. The electrode layer 208, the piezoelectric layer 210 and the electrode layer 212 form a metal-piezoelectric-metal structure 214. Further, the electrode layer 208 serves as a bottom electrode, while the electrode layer 212 serves as a top electrode. As mentioned above, the piezoelectric layer 210 is configured to sense motion and to convert the motion into an electrical signal through the bottom electrode (i.e., the electrode layer 108) and the top electrode (i.e., the electrode layer 112). Thus, the metal-piezoelectric-metal structure 214 serves as a MEMS device that may be used in a microphone, an accelerometer, a motion sensor, a pressure sensor, or a gyroscope. In addition, the piezoelectric layer 210 is configured to actuate input electrical signal from IC device. The metal-piezoelectric-metal structure 214 serves as a MEMS device that may be used in a micro-speaker, a micropump, or an autofocus device. Additionally, the metal-piezoelectric-metal structure 214 is electrically coupled to an IC device in the IC region through the BEOL interconnect structure, though not shown.

Still referring to FIG. 7, in some embodiments, a diffusion barrier layer 216 and a dielectric layer 218 may be formed over the metal-piezoelectric-metal structure 214 and the substrate 200 after the forming of the electrode layer 212. In some embodiments, the diffusion barrier layer 216 and the dielectric layer 218 may be formed to cover the metal-piezoelectric-metal structure 214 and extend from the anchor portion 206 to the movable portion 204. However, in some embodiments, the diffusion barrier layer 216 may be formed to cover the metal-piezoelectric-metal structure 214 and a portion of the substrate 200 in the anchor portion 206. In such embodiments, portions of the movable portion 204 in the MEMS region are free of the diffusion barrier layer 216 in order to reduce film stiffness.

As shown in FIG. 7, in some embodiments, patterned conductive layers 220 and 222 are formed over the substrate 200 and the metal-piezoelectric-metal structure 214. Further, the patterned conductive layers 220 and 222 are formed in the anchor portion 206. The forming of the patterned conductive layers 220 and 222 may be similar to the forming of the patterned conductive layers 120 and 122; therefore, such details are omitted. Further, materials for forming the patterned conductive layers 220 and 222 are similar to those of the patterned conductive layers 120 and 122; therefore, such details are also omitted. In some embodiments, a glue layer 224 and/or a diffusion barrier layer 224 may be formed prior to the forming of the patterned conductive layers 220 and 222 in order to improve adhesion between the patterned conductive layers 220, 222 and the underlying layers and to mitigate diffusion into the dielectric layer 218. As shown in FIG. 7, the patterned conductive layer 220 is formed over a portion of the metal-piezoelectric-metal structure 214 and coupled to the electrode layer 212, and the patterned conductive layer 222 is formed over another portion of the metal-piezoelectric-metal structure 214 and coupled to the electrode layer 208. As shown in FIG. 7, a step height is formed between a top surface of the patterned conductive layer 220 and the dielectric layer 218, and a step height is formed between a top surface of the patterned conductive layer 222 and the dielectric layer 218. Such step heights form an uneven topography over the substrate 200.

Please refer to FIGS. 7, 3B and 3C, wherein FIG. 3B is a partially enlarged view of circle A1 in FIG. 7, and FIG. 3C is a partially enlarged view of circle A2 in FIG. 7. In some embodiments, a dielectric layer 230 is formed over the substrate 200 and the metal-piezoelectric-metal structure 214. In some embodiments, a glue layer 232 and/or a diffusion barrier layer 232 may be formed prior to the forming of the dielectric layer 230. The glue layer 232 and/or the diffusion barrier layer 232 is formed in order to improve adhesion between the dielectric layer 230 and the underlying layers and to mitigate diffusion into the dielectric layer 230. In some embodiments, the dielectric layer 230 may include silicon oxide, but the disclosure is not limited thereto. In some embodiments, a thickness of the dielectric layer 230 is between approximately 100 Å and approximately 5,000 Å, but the disclosure is not limited thereto.

As shown in FIGS. 7, 3B, and 3C, a corner C1 (shown in FIG. 3B) may be formed by the patterned conductive layer 220 and the dielectric layer 218, wherein the corner C1 has an included angle θ1 defined by the patterned conductive layer 220 and the dielectric layer 218. In some embodiments, the included angle θ1 of the corner C1 is equal to or less than 90°. A corner C2 (shown in FIG. 3C) may be formed by the patterned conductive layer 220, wherein the corner C2 has an included angle θ2 defined by the patterned conductive layer 220. In the included angle θ2 of the corner C2 is equal to or less than 90°. Additionally, a seam S may be formed between the patterned conductive layer 222 and the dielectric layer 218. As mentioned above, it is difficult to fill the corners C1 and C2 and the seam S due to such the topography. To mitigate such issue, the dielectric layer 230 is formed by a CVD with a liquid phase precursor, such as TEOS. In some embodiments, the dielectric layer 230 is formed using an FCVD. In such embodiments, the corners C1 and C2 and the seam S can be filled with the dielectric layer 230. In some comparative approaches, when a dielectric layer is formed without the liquid phase precursor, it is found that a void is usually sealed within the corner C1 and such dielectric layer, sealed within the corner C2 and such dielectric layer, and/or sealed within the seam S and such dielectric layer. In contrast to those comparative approaches, in some embodiments, of the present disclosure, the corners C1 and C2 and the seam S can be filled with the dielectric layer 230. Further, the dielectric layer 230 has a corner C3 corresponding to the corners C1 and C2. The corner C3 of the dielectric layer 230 has a concave surface, as shown in FIGS. 3B and 3C.

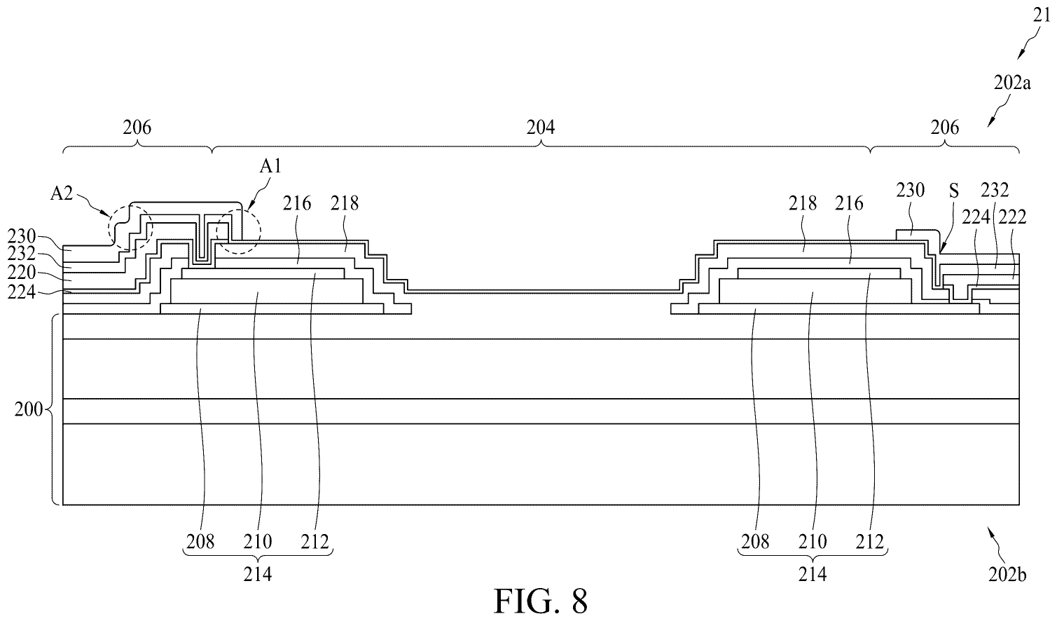

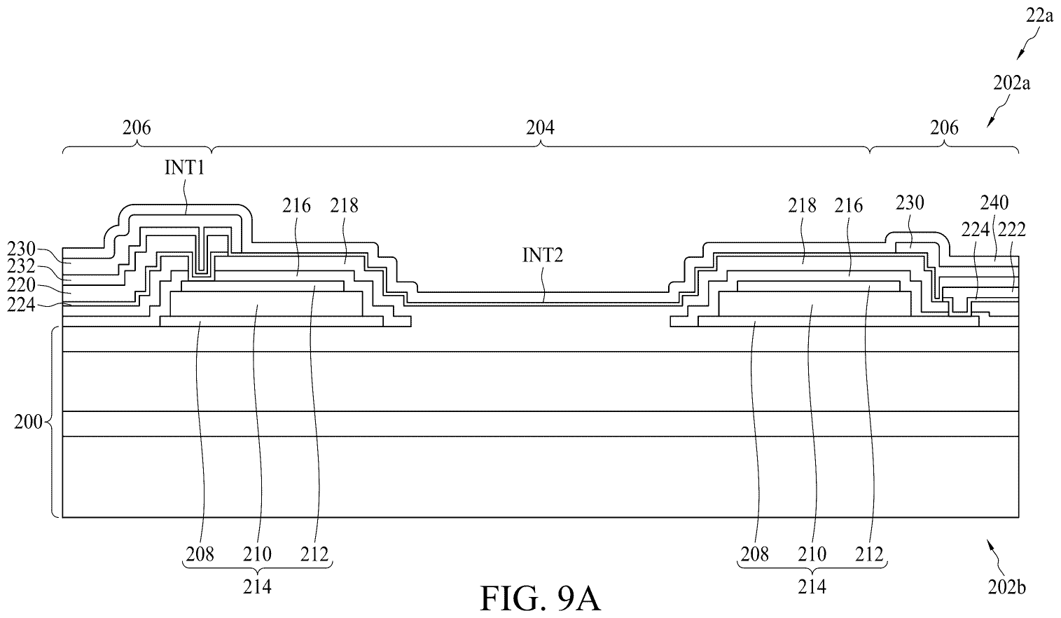

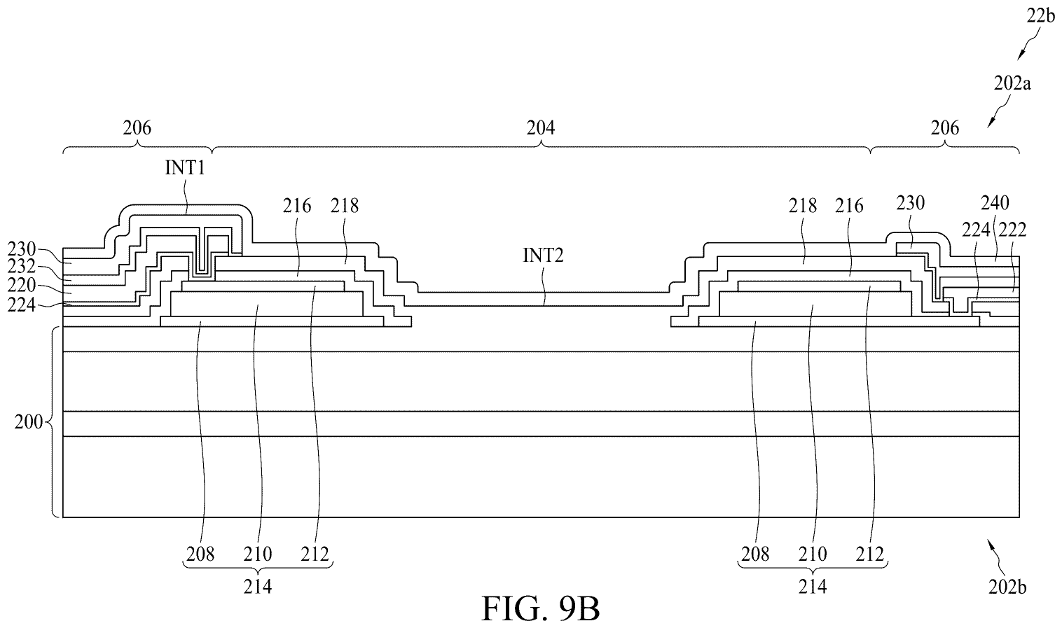

Referring to FIG. 8, in some embodiments, a portion of the dielectric layer 230 is removed from the movable portion 204 of the substrate 200. In such embodiments, the patterned conductive layers 220 and 222 in the anchor portion 206 are still entirely covered by the dielectric layer 230. However, a portion of the metal-piezoelectric-metal structure 214 that is in the movable portion 204 may be exposed through the dielectric layer 230. Additionally, in some embodiments, the glue layer/diffusion barrier layer 232 may be left over the movable portion 204 of the substrate 200, as shown in FIG. 8. In some alternative embodiments, the glue layer/diffusion barrier layer 232 may be removed from the movable portion 204 simultaneously with the removing of the dielectric layer 230 (shown in FIG. 9B).

Referring to FIGS. 9A and 9B, in some embodiments, a dielectric layer 240 is formed on the front side 202a. The dielectric layer 240 includes a material different from that of the dielectric layer 230. In some embodiments, the dielectric layer 240 includes silicon nitride, aluminum nitride, silicon oxynitride or aluminum oxynitride, but the disclosure is not limited thereto. In some embodiments, a thickness of the dielectric layer 240 is between approximately 1,000 Å and approximately 4,000 Å, but the disclosure is not limited thereto. It should be noted that due to the concave surface provided by the dielectric layer 230, the dielectric layer 240 can be formed to sufficiently cover the patterned conductive layers 220 and 222.

As mentioned above, the dielectric layer 230 and the dielectric layer 240 form a bi-layer structure. In the bi-layer structure, the dielectric layer 230 provides a concave surface such that a filling result of the dielectric layer 240 is improved. Further, the dielectric layer 240 can provide moisture protection with a less thickness, thus reducing film stiffness. Accordingly, actuation performance of the MEMS device is improved. Additionally, in such bi-layer structure, planarization is not needed. Therefore, the MEMS device is protected from external mechanical stress or force.

Still referring to FIG. 9A, in some embodiments, due to the removal of the portion of the dielectric layer 230 from the movable portion 204, the dielectric layer 240 may be in contact with the glue layer 232 and/or the diffusion barrier layer 232. In such embodiments, two interfaces are obtained. As shown in FIG. 9A, the dielectric layer 240 covers and is in contact with a top surface and a sidewall of the dielectric layer 230 in the anchor portion 206; therefore, a first interface INT1 is formed by the dielectric layer 230 and the dielectric layer 240. In the movable portion 204, the dielectric layer 240 covers and is in contact with the glue layer 232 and/or the diffusion barrier layer 232; therefore, a second interface INT2 is formed by the dielectric layer 240 and the glue layer 232 and/or the diffusion barrier layer 232. In other words, the dielectric layer 240 may have two different interfaces INT1 and INT2.

Referring to FIG. 9B, in some embodiments, when the glue layer 232 and/or the diffusion barrier layer 232 is removed from the movable portion 204 together with the dielectric layer 230, interfaces may be formed, with variations in different situations. For example, in some embodiments, when the dielectric layer 230 and the dielectric layer 218 include a same material such as, for example but not limited thereto, silicon oxide, one interface may be obtained. In such embodiments, the dielectric layer 240 covers and is in contact with a top surface and sidewalls of the dielectric layer 230 in the anchor portion 206, while the dielectric layer 240 covers and is in contact with the dielectric layer 218 in the movable portion 204. Accordingly, one interface is formed between the dielectric layer 230 and the dielectric layer 240, and between the dielectric layer 218 and the dielectric layer 240.

In other embodiments, when the dielectric layer 230 and the dielectric layer 218 include different materials, two interfaces may be obtained. As shown in FIG. 9B, the dielectric layer 240 covers and is in contact with a top surface and a sidewall of the dielectric layer 230 in the anchor portion 206; therefore, a first interface INT1 is formed by the dielectric layer 230 and the dielectric layer 240. In the movable portion 204, the dielectric layer 240 covers and is in contact with the dielectric layer 218; therefore, a second interface INT2 is formed by the dielectric layer 218 and the dielectric layer 240. In other words, the dielectric layer 240 may have two different interfaces INT1 and INT2.

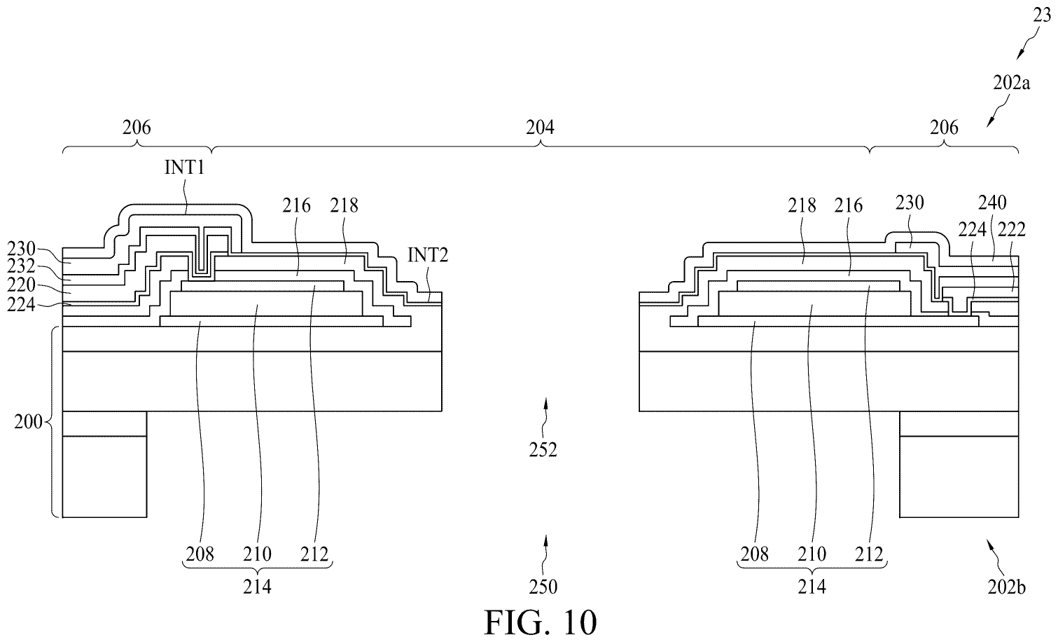

Referring to FIG. 10, in some embodiments, a portion of the substrate 200 is removed from a backside 202b to form an environment port 250 in communication with an ambient environment. In some embodiments, a portion of the substrate 200, a portion of the dielectric layer 218 and a portion of the dielectric layer 240 are removed from the movable portion 204 of the MEMS region to form a hole 252. As shown in FIG. 10, the hole 252 is coupled to the environment port 250. Further, a diameter or a width of the hole 252 is less than a diameter or a width of the environment port 250. In such embodiments, a portion of the substrate 200, a portion of the dielectric layer 218 and a portion of the dielectric layer 240 form sidewalls of the hole 252, as shown in FIG. 10.

Accordingly, a MEMS device 23 is formed as shown in FIG. 10. In some embodiments, the MEMS device 23 includes a substrate 200, a metal-piezoelectric-metal structure 214 formed on a front side 202a of the substrate 200, patterned conductive layers 220 and 222, a dielectric layer 230 formed over the patterned conductive layers 220 and 222, and a dielectric layer 240 formed over the first dielectric layer 230. The metal-piezoelectric-metal structure 214 includes an electrode layer 208 serving as a bottom electrode, an electrode layer 212 serving as a top electrode, and a piezoelectric layer 210 between the bottom and top electrodes 208 and 212. The patterned conductive layer 220 is coupled to the top electrode 212, and the patterned conductive layer 222 is coupled to the bottom electrode 208. The dielectric layer 230 covers the patterned conductive layers 220 and 222 and a portion of the metal-piezoelectric-metal structure 214. However, the movable portion 204 of the substrate 200 is free of the dielectric layer 230. The dielectric layer 240 is formed over the dielectric layer 230 and the substrate 200. Further, the dielectric layer 240 extends from the anchor portion 206 to the movable portion 204. As mentioned above, the dielectric layers 230 and 240 form a bi-layer structure. In the bi-layer structure, the dielectric layer 240 provides moisture protection, while the dielectric layer 230 provides a concave surface for improving a filling result such that the dielectric layer 240 can be thoroughly formed over the patterned conductive layers 220 and 222.

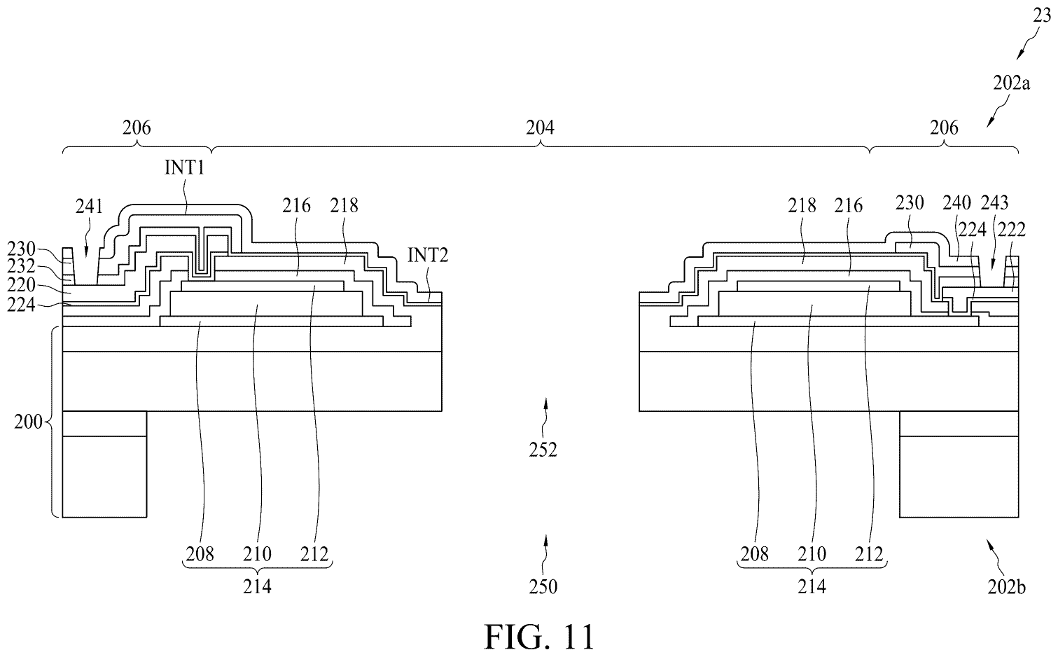

In addition, referring to FIG. 11, in some embodiments, a portion of the dielectric layer 240, a portion of the dielectric layer 230 and a portion of the glue layer 232 and/or the diffusion barrier layer 232 may be removed to form openings 241 and 243. The opening 241 may expose a portion of the patterned conductive layer 220, and the opening 243 may expose a portion of the patterned conductive layer 222. In some embodiments, the patterned conductive layers 220 and 222 serve as topmost metal layers, and a probing can be performed on the patterned conductive layers 220 and 222 through the openings 241 and 243. Additionally, the forming of the openings 241 and 243 may be performed prior to or after the forming of the environment port 250.

Referring to FIG. 12, a method for forming a MEMS device 30 is provided. While the disclosed method 30 is illustrated and described herein as a series of acts or operations, it will be appreciated that an order of the illustrated acts or operations is not to be interpreted in a limiting sense. For example, some operations may occur in different orders and/or concurrently with other acts or operations apart from those illustrated and/or described herein. In addition, not all illustrated operations may be required to implement one or more aspects or embodiments of the method disclosed herein. Further, one or more of the operations depicted herein may be carried out in one or more separate operations and/or phases.

In operation 302, a substrate 100 is received. FIG. 1 shows an intermediate MEMS device 10 in accordance with some embodiments corresponding to operation 302. The substrate 100 may have a first side 102a and a second side 102b opposite to the first side 102a. In some embodiments, the first side 102a is a front side, and the second side 102b is a backside. As shown in FIG. 1, at least a metal-piezoelectric-metal structure 114 is formed over the first side 102a of the substrate 100. As mentioned above, the metal-piezoelectric-metal structure 114 is disposed in a MEMS region of the substrate 100. Further, the substrate 100 may include IC devices disposed in an IC region, and a BEOL interconnect structure is disposed over the first side 102a. The BEOL interconnect structure may be electrically coupled the metal-piezoelectric-metal structure 114 to the IC devices, though not shown. The metal-piezoelectric-metal structure 114 includes electrode layers 108 and 112 and a piezoelectric layer 110 between the electrode layers 108 and 112. In some embodiments, a dielectric layer 118 may be formed to cover the metal-piezoelectric-metal structure 114.

In accordance with some embodiments, FIG. 7 shows an intermediate MEMS device 20 corresponding to operation 302.

In operation 304, patterned conductive layers 120 and 122 are formed over the substrate 100 and the metal-piezoelectric-metal structure 114. FIG. 2 shows an intermediate MEMS device 11 in accordance with some embodiments corresponding to operation 304. As shown in FIG. 2, the patterned conductive layer 120 is coupled to the top electrode (i.e., the electrode layer 112), and the patterned conductive layer 122 is coupled to the bottom electrode (i.e., the electrode layer 108).

In accordance with some embodiments, FIG. 7 also shows the MEMS device 20 corresponding to operation 304.

In operation 306, a first dielectric layer 130 is formed over the patterned conductive layers 120 and 122. FIG. 3A shows an intermediate MEMS device 12 in accordance with some embodiments corresponding to operation 306. In some embodiments, the first dielectric layer 130 is formed by a CVD with fluid phase precursor or an FCVD, such that a gap-filling result is improved even though the patterned conductive layers 120 and 122 create an uneven topography, which usually poses a challenge for film deposition. Accordingly, corners C1 and C2 and seams S over the patterned conductive layers 120 and 122 are filled with the first dielectric layer 130. Further, a corner C3 of the dielectric layer 130 corresponding to the corners C1 and C2 has a concave configuration, which is beneficial for subsequent film formation.

In accordance with some embodiments, FIG. 7 also shows the intermediate MEMS device 20 corresponding to operation 306.

In operation 307, a portion of the first dielectric layer 130 is removed. FIG. 8 illustrates an intermediate MEMS device 21 in accordance with some embodiments corresponding to operation 307. As shown in FIG. 8, the substrate 200 has a movable portion 204 and an anchor portion 206 surrounding the movable portion 204. In some embodiments, a portion of the first dielectric layer 230 is removed from the movable portion 204 of the substrate 200. Accordingly, a glue layer 232 and/or a diffusion barrier layer 232, or a dielectric layer 218, is exposed.

In operation 308, a second dielectric layer 140 or 240 is formed. FIG. 4 shows an intermediate MEMS device 13 in accordance with some embodiments corresponding to operation 308. Further, FIGS. 9A and 9B respectively show intermediate MEMS devices 22a and 22b in accordance with some embodiments corresponding to operation 308. It should be noted that in some embodiments, operation 308 can be performed after operation 307. In some other embodiments, operation 308 can be performed after operation 306, while operation 307 is omitted. As shown in FIGS. 4, 9A and 9B, the second dielectric layer 140 or 240 is formed to cover the first dielectric layer 130 or 230. Further, the second dielectric layer 140 or 240 extends from the anchor portion 106, 206 into the movable portion 104 or 204.

In operation 310, a portion of the substrate 100 is removed from the second side 102b to form an environment port 150. FIG. 5 shows a cross-sectional view of an intermediate semiconductor package structure 14 in accordance with some embodiments corresponding to operation 310. In accordance with some embodiments, FIG. 10 shows the intermediate MEMS device 23 corresponding to operation 310.

According to the method 30, the dielectric layers 130 and 140 (or the dielectric layers 230 and 240) form a bi-layer structure. In the bi-layer structure, the dielectric layer 140 or 240 provides a moisture protection, while the dielectric layer 130 or 230 provides a concave configuration for improving film formation of the second dielectric layer 140 or 240 such that the second dielectric layer 140, 240 can be thoroughly formed over the patterned conductive layers 120 and 122, or 220 and 222. Further, the second dielectric layer 140 or 240 is able to provide sufficient moisture protection with relatively less thickness, thus reducing film stiffness. Accordingly, actuation performance of the MEMS device is improved. Additionally, with such bi-dielectric structure, planarization is not needed. Therefore, the MEMS device is protected from external mechanical stress or force.

Accordingly, the present disclosure provides a MEMS device and a method of forming a bi-layer structure that is able to provide sufficient protection to the piezoelectric MEMS device. Further, with such bi-layer structure, no planarization operation is required. Therefore, mechanical influence on the piezoelectric MEMS device is mitigated.

In some embodiments, a MEMS device is provided. The MEMS device includes a substrate, a first electrode layer, a second electrode layer, a piezoelectric layer, a first dielectric layer and a second dielectric layer. The substrate includes a movable portion and an anchor portion. The first electrode layer is disposed over the substrate, the second electrode layer is disposed over the first electrode layer, and the piezoelectric layer is disposed between the first electrode layer and the second electrode layer. The second dielectric layer is disposed over the first dielectric layer, and extends from the anchor portion into the movable portion. The first dielectric layer and the second dielectric layer include different materials.

In some embodiments, a MEMS device is provided. The MEMS device includes a substrate having an environment port in communication with an ambient environment, a metal-piezoelectric-metal structure disposed over the substrate, a first conductive layer, a second conductive layer, a first dielectric layer and a second dielectric layer. The first conductive layer is disposed over the metal-piezoelectric-metal structure and the substrate. The second conductive layer is disposed over the metal-piezoelectric-metal structure and the substrate, and separated from the first conductive layer. The first dielectric layer is conformally disposed over the first conductive layer and the second conductive layer. The second dielectric layer is conformally disposed over the first dielectric layer, the first conductive layer and the second conductive layer, and overlaps the environment port. The second dielectric layer covers a top surface and a sidewall of the first dielectric layer.

In some embodiments, a method for forming a MEMS device is provided. The method includes the following operations. A substrate having a first side and a second side opposite to the first side is received. A metal-piezoelectric-metal structure is formed over the first side of the substrate. Patterned conductive layers are formed over the substrate and the metal-piezoelectric-metal structure. A first dielectric layer is formed over the patterned conductive layers. A second dielectric layer is formed over the first dielectric layer. The first dielectric layer and the second dielectric layer include different materials. A thickness of the second dielectric layer is greater than a thickness of the first dielectric layer.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A microelectromechanical system (MEMS) device comprising:
a substrate comprising a movable portion and an anchor portion;
a first electrode layer disposed over the substrate;
a second electrode layer disposed over the first electrode layer;
a piezoelectric layer disposed between the first electrode layer and the second electrode layer;
a first dielectric layer disposed over the first electrode layer, the second electrode layer and the piezoelectric layer; and
a second dielectric layer disposed over the first electric layer and extends from the anchor portion into the movable portion,
wherein the first dielectric layer and the second dielectric layer include different materials.

2. The MEMS device of claim 1, wherein the substrate comprises an environment port in communication with an ambient environment.

3. The MEMS device of claim 1, wherein the first dielectric layer extends from the anchor portion to the movable portion.

4. The MEMS device of claim 1, wherein the movable portion is free of the first dielectric layer.

5. The MEMS device of claim 1, further comprising:
a first conductive layer coupled to the first electrode layer; and
a second conductive layer coupled to the second electrode layer.

6. The MEMS device of claim 5, wherein the first dielectric layer and the second dielectric layer cover the first conductive layer and the second conductive layer.

7. The MEMS device of claim 6, further comprising a glue layer between the first dielectric layer and the first conductive layer, and between the first dielectric layer and the second conductive layer.

8. A microelectromechanical system (MEMS) device comprising:
a substrate having an environment port in communication with an ambient environment;
a metal-piezoelectric-metal structure disposed over the substrate;
a first conductive layer disposed over the metal-piezoelectric-metal structure and the substrate;
a second conductive layer disposed over the metal-piezoelectric-metal structure and the substrate, and separated from the first conductive layer;
a first dielectric layer conformally disposed over the first conductive layer and the second conductive layer; and
a second dielectric layer conformally disposed over the first dielectric layer, the first conductive layer and the second conductive layer, and overlaps the environment port,
wherein the second dielectric layer covers a top surface and a sidewall of the first dielectric layer.

9. The MEMS device of claim 8, wherein the first conductive layer has a corner, and the corner has an included angle equal to or less than 90°.

10. The MEMS device of claim 9, wherein the first dielectric layer has a corner corresponding to the corner of the first conductive layer, and the corner of the first dielectric layer has a concave surface.

11. The MEMS device of claim 8, wherein the substrate has a movable portion and an anchor portion, and first dielectric layer and the second dielectric layer extend from the anchor portion to the movable portion.

12. The MEMS device of claim 11, wherein the substrate has a movable portion and an anchor portion, the second dielectric layer extends from the anchor portion to the movable portion, and the movable portion is free of the first dielectric layer.

13. The MEMS device of claim 8, wherein the metal-piezoelectric-metal structure comprises:
a first electrode layer;
a second electrode over the first electrode layer; and
a piezoelectric layer between the first electrode layer and the second electrode layer, wherein the first conductive layer is coupled to the first electrode layer, and the second conductive layer is coupled to the second electrode layer.

14. The MEMS device of claim 8, wherein a moisture resistance of the second dielectric layer is greater than that of the first dielectric layer.

15. The MEMS device of claim 8, wherein the first dielectric layer and the second dielectric layer comprise different materials.

16. A method for forming a MEMS device, comprising:
receiving a substrate having a first side and a second side opposite to the first side, wherein a metal-piezoelectric-metal structure is formed over the first side of the substrate;
forming patterned conductive layers over the substrate and the metal-piezoelectric-metal structure;
forming a first dielectric layer over the patterned conductive layers; and
forming a second dielectric layer over the first dielectric layer,
wherein the first dielectric layer and the second dielectric layer comprise different materials, and a thickness of the second dielectric layer is equal to or greater than a thickness of the first dielectric layer.

17. The method of claim 16, wherein the substrate has a movable portion and an anchor portion.

18. The method of claim 17, further comprising removing a portion of the first dielectric layer from the movable portion.

19. The method of claim 17, wherein the first dielectric layer comprises a flowable material that is formed by performing a flowable chemical vapor deposition (FCVD) with a liquid phase precursor.

20. The method of claim 16, further comprising removing a portion of the substrate from the second side to form an environment port.
